(19) United States
(12) Patent Application Publication
(10) Pub. No.: US 2022/0392748 A1
(43) Pub. Date: Dec. 8, 2022

(54) PLASMA PROCESSING APPARATUS AND PLASMA PROCESSING METHOD

(71) Applicant: Tokyo Electron Limited, Tokyo (JP)

(72) Inventor: Akira KAIJIMA, Miyagi (JP)

(73) Assignee: Tokyo Electron Limited, Tokyo (JP)

(21) Appl. No.: 17/830,744

(22) Filed: Jun. 2, 2022

(30) Foreign Application Priority Data
Jun. 2, 2021 (JP) 2021-092775

(51) Int. Cl. H01J 37/32

(52) U.S. Cl. CPC H01J 37/32091; H01J 37/321; H01J 37/3244; H01J 2237/20

(57) ABSTRACT

A plasma processing apparatus in which a radio-frequency power supply modulates radio-frequency power such that the level of the radio-frequency power in a first period is higher than the level of the radio-frequency power in a second period. The second period alternates with the first period. A bias power supply modulates bias energy such that the level of the bias energy in a third period is higher than the level of the bias energy in a fourth period. The fourth period alternates with the third period. The bias power supply adjusts the time difference between the start point of the first period and the start point of the third period which partially overlaps with the first period according to the power coupling efficiency of the radio-frequency power to the plasma, obtained from a power of a traveling wave and a power of a reflected wave.

### CROSS-REFERENCE TO RELATED APPLICATIONS

This application is based on and claims priority from Japanese Patent Application No. 2021-092775, filed on Jun. 2, 2021 with the Japan Patent Office, the disclosure of which is incorporated herein in its entirety by reference.

### TECHNICAL FIELD

The present disclosure relates to a plasma processing apparatus and a plasma processing method.

### BACKGROUND

A plasma processing apparatus is used for plasma processing of a substrate. In the plasma processing apparatus, radio-frequency power is supplied to generate plasma from a gas within a chamber. Japanese Patent Laid-Open Publication No. H10-064696 discloses a technique to perform the On/Off control or high/low control of radio-frequency power.

### SUMMARY

In one embodiment, a plasma processing apparatus is provided. The plasma processing apparatus includes a chamber, a substrate support, a radio-frequency power supply, a bias power supply, and a gauge. The substrate support has an electrode and is provided within the chamber. The radio-frequency power supply is configured to supply radio-frequency power in order to generate a plasma from a gas within the chamber. The bias power supply is configured to apply bias energy to the electrode of the substrate support in order to draw ions from the plasma to a substrate placed on the substrate support. The gauge is configured to measure a power of a traveling wave and a power of a reflected wave of the radio-frequency power. The radio-frequency power supply modulates the radio-frequency power such that a level of the radio-frequency power in a first period is higher than a level of the radio-frequency power in a second period. The second period alternates with the first period. The bias power supply modulates the bias energy such that a level of the bias energy in a third period is higher than a level of the bias energy in a fourth period. The fourth period alternates with the third period. The bias power supply adjusts a time difference between a start point of the first period and a start point of the third period that partially overlaps with the first period according to a power coupling efficiency of the radio-frequency power to the plasma, obtained from the power of the traveling wave and the power of the reflected wave.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a diagram schematically illustrating a plasma processing apparatus according to one embodiment.

FIG. 2 is a diagram schematically illustrating a plasma processing apparatus according to one embodiment.

FIG. 3 is a timing chart of an example of radio-frequency power and bias energy.

FIG. 4 is a diagram illustrating a time change in power coupling efficiency.

FIG. 5 is a flowchart of a plasma processing method according to one embodiment.

### DESCRIPTION OF EMBODIMENT

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, various embodiments will be described.

In one embodiment, a plasma processing apparatus is provided. The plasma processing apparatus includes a chamber, a substrate support, a radio-frequency power supply, a bias power supply, and a gauge. The substrate support includes an electrode and is provided within the chamber. The radio-frequency power supply is configured to supply radio-frequency power in order to generate plasma from a gas within the chamber. The bias power supply is configured to apply bias energy to the electrode of the substrate support in order to draw ions from the plasma to a substrate placed on the substrate support. The gauge is configured to measure a power of a traveling wave and a power of a reflected wave of the radio-frequency power. The radio-frequency power supply modulates the radio-frequency power such that a level of the radio-frequency power in a first period is higher than a level of the radio-frequency power in a second period. The second period alternates with the first period. The bias power supply modulates the bias energy such that a level of the bias energy in a third period is higher than a level of the bias energy in a fourth period. The fourth period alternates with the third period. The bias power supply adjusts a time difference between a start point of the first period and a start point of the third period that partially overlaps with the first period according to a power coupling efficiency of the radio-frequency power to the plasma, obtained from the power of the traveling wave and the power of the reflected wave.

The time difference between the first period and the third period affects the coupling efficiency of the radio-frequency power to the plasma. According to the above embodiment, since the time difference is adjusted according to the power coupling efficiency of the radio-frequency power to the plasma, it is possible to increase the power coupling efficiency of the radio-frequency power in the generation of the plasma.

In one embodiment, the bias power supply may be configured to adjust the time difference such that the start point of the third period precedes the start point of the first period, and the time difference increases as the power coupling efficiency decreases.

In one embodiment, the bias power supply may set a time length of the third period such that an end point of the first period coincides with an end point of the third period that partially overlaps with the first period.

In one embodiment, the bias energy may be radio-frequency power or a pulse of a voltage that is periodically generated.

In one embodiment, the radio-frequency power supply may be configured to stop supply of the radio-frequency power in the second period. The bias power supply may be configured to stop supply of the bias energy in the fourth period.

In another embodiment, a plasma processing method is provided. The plasma processing method includes placing a substrate on a substrate support provided within a chamber of a plasma processing apparatus. The plasma processing method further includes modulating radio-frequency power supplied to generate a plasma within the chamber. The radio-frequency power is modulated such that a level of the radio-frequency power in the first period is higher than a level of the radio-frequency power in the second period. The second period alternates with the first period. The plasma processing method further includes modulating bias energy supplied to an electrode of the substrate support in order to draw ions from the plasma to the substrate. The bias energy is modulated such that a level of the bias energy in a third period is higher than a level of the bias energy in a fourth period. The fourth period alternates with the third period. The plasma processing method further includes adjusting a time difference between a start point of the first period and a start point of the third period that partially overlaps with the first period according to a power coupling efficiency of the radio-frequency power to the plasma. The power coupling efficiency is obtained from a power of a traveling wave of the radio-frequency power and a power of a reflected wave of the radio-frequency power.

In one embodiment, the time difference may be adjusted such that the start point of the third period precedes the start point of the first period, and the time difference increases as the power coupling efficiency decreases.

In one embodiment, a time length of the third period may be set such that an end point of the first period coincides with an end point of the third period that partially overlaps with the first period.

In one embodiment, the bias energy may be radio-frequency power or a pulse of a voltage that is periodically generated.

In one embodiment, supply of the radio-frequency power may be stopped in the second period. Supply of the bias energy may be stopped in the fourth period.

Hereinafter, various embodiments will be described in detail with reference to the drawings. In addition, the same reference numerals will be given to the same or corresponding parts in each drawing.

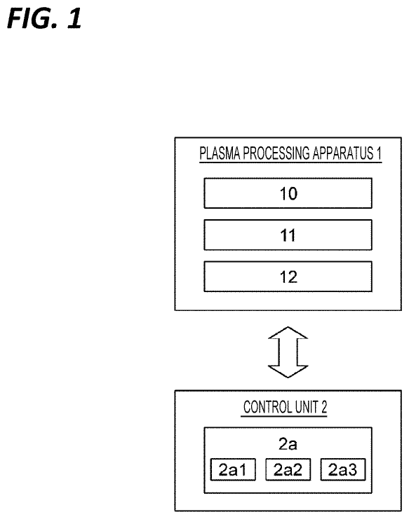

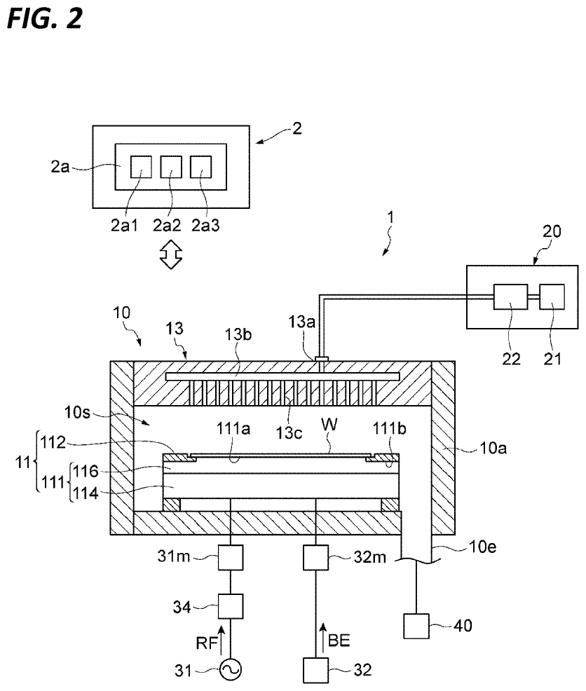

FIGS. 1 and 2 are diagrams schematically illustrating a plasma processing apparatus according to one embodiment.

In one embodiment, a plasma processing system includes a plasma processing apparatus 1 and a control unit 2. The plasma processing apparatus 1 includes a plasma processing chamber 10, a substrate support unit 11, and a plasma generation unit 12. The plasma processing chamber 10 has a plasma processing space. Further, the plasma processing chamber 10 has at least one gas supply port for supplying at least one processing gas to the plasma processing space and at least one gas discharge port for exhausting the gas from the plasma processing space. The gas supply port is connected to a gas supply unit 20 to be described later, and the gas discharge port is connected to an exhaust system 40 to be described later. The substrate support unit 11 is placed in the plasma processing space and has a substrate support surface for supporting the substrate.

The plasma generation unit 12 is configured to generate plasma from at least one processing gas supplied into the plasma processing space. The plasma generated in the plasma processing space may be, for example, capacitively-coupled plasma (CCP), inductively-coupled plasma (ICP), electron-cyclotron-resonance (ECR) plasma, helicon-wave plasma (HWP), or surface-wave plasma (SWP). Further, various types of plasma generators including an alternating current (AC) plasma generator and a direct current (DC) plasma generator may be used. In one embodiment, an AC signal (AC power) used in the AC plasma generator has a frequency within the range of 100 kHz to 10 GHz. Thus, the AC signal includes a radio frequency (RF) signal and a microwave signal. In one embodiment, the RF signal has a frequency within the range of 200 kHz to 150 MHz.

The control unit 2 processes a computer executable command which causes the plasma processing apparatus 1 to execute various steps described in the present disclosure. The control unit 2 may be configured to control each element of the plasma processing apparatus 1 so as to execute various steps described herein. In one embodiment, a part or the entirety of the control unit 2 may be provided in the plasma processing apparatus 1. The control unit 2 may include, for example, a computer 2a. The computer 2a may include, for example, a central processing unit (CPU) 2a1, a storage unit 2a2, and a communication interface 2a3. The processing unit 2a1 may be configured to perform various control operations based on a program stored in the storage unit 2a2. The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

Hereinafter, a configuration example of a capacitively-coupled plasma processing apparatus will be described as an example of the plasma processing apparatus 1. The capacitively-coupled plasma processing apparatus 1 includes the plasma processing chamber 10, the gas supply unit 20, a plurality of power supplies, and the exhaust system 40. Further, the plasma processing apparatus 1 includes the substrate support unit 11 and a gas introducing unit. The gas introducing unit is configured to introduce at least one processing gas into the plasma processing chamber 10. The gas introducing unit includes a shower head 13. The substrate support unit 11 is disposed within the plasma processing chamber 10. The shower head 13 is disposed above the substrate support 11. In one embodiment, the shower head 13 constitutes at least a portion of the ceiling of the plasma processing chamber 10. The plasma processing chamber 10 has a plasma processing space 10s defined by the shower head 13, a sidewall 10a of the plasma processing chamber 10 and the substrate support unit 11. The sidewall 10a is grounded. The shower head 13 and the substrate support unit 11 are electrically insulated from a housing of the plasma processing chamber 10.

The substrate support unit 11 includes a main body portion 111 and a ring assembly 112. The main body portion 111 has a central region (substrate support surface) 111a for supporting a substrate (wafer) W and an annular region (ring support surface) 111b for supporting the ring assembly 112. The annular region 111b of the main body portion 111 surrounds the central region 111a of the main body portion 111 in a plan view. The substrate W is placed on the central region 111a of the main body portion 111, and the ring assembly 112 is placed on the annular region 111b of the main body portion 111 so as to surround the substrate W on the central region 111a of the main body portion 111.

In one embodiment, the main body portion 111 includes a base 114 and an electrostatic chuck 116. The base 114 includes a conductive member. The conductive member of the base 114 functions as a lower electrode. The electrostatic chuck 116 is disposed on the base 114. The upper surface of the electrostatic chuck 116 has the substrate support surface 111a. The ring assembly 112 includes one or a plurality of annular members. At least one of the one or plurality of annular members is an edge ring. Further, although not illustrated, the substrate support unit 11 may include a temperature regulation module configured to regulate at least one of the electrostatic chuck 116, the ring assembly 112, and the substrate W to a target temperature. The temperature regulation module may be a heater, a heat transfer medium, a flow path, or a combination thereof. A heat transfer fluid such as a brine or a gas flows through the flow path. Further, the substrate support 11 may include a heat transfer gas supply configured to supply a heat transfer gas to a gap between the back surface of the substrate W and the substrate support surface 111a.

The shower head 13 is configured to introduce at least one processing gas from the gas supply unit 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes a conductive member. The conductive member of the shower head 13 functions as an upper electrode. In addition, in addition to the shower head 13, the gas introducer may include one or a plurality of side gas injectors (SGI) attached to one or a plurality of openings formed in the sidewall 10a.

The gas supply unit 20 may include at least one gas source 21 and at least one flow rate controller 22. In one embodiment, the gas supply unit 20 is configured to supply at least one processing gas from each corresponding gas source 21 to the shower head 13 via each corresponding flow rate controller 22. Each flow rate controller 22 may include, for example, a mass flow controller or a pressure control type flow rate controller. Furthermore, the gas supply unit 20 may include at least one flow rate modulation device that modulates or pulses the flow rate of at least one processing gas.

The exhaust system 40 may be connected to, for example, a gas outlet 10e provided in a bottom portion of the plasma processing chamber 10. The exhaust system 40 may include a pressure adjustment valve and a vacuum pump. The pressure within the plasma processing space 10s is adjusted by the pressure adjustment valve. The vacuum pump may include a turbo molecular pump, a dry pump, or a combination thereof.

The plurality of power supplies of the plasma processing apparatus 1 include a radio-frequency power supply 31 and a bias power supply 32. The radio-frequency power supply 31 is configured to supply radio-frequency power RF in order to generate a plasma from the gas within the chamber 10. The radio-frequency power RF has a frequency within the range of 13 MHz to 150 MHz. The radio-frequency power supply 31 is connected to an electrode (for example, the base 114) of the substrate support 11 via a matching unit 31m. The matching unit 31m includes a matching circuit for matching the impedance of the load of the radio-frequency power supply 31 with the output impedance of the radio-frequency power supply 31. In addition, the radio-frequency power supply 31 may be connected to another electrode of the substrate support unit 11 instead of the base 114. Alternatively, the radio-frequency power supply 31 may be connected to an upper electrode via the matching unit 31m.

The bias power supply 32 is electrically connected to the electrode (e.g., the base 114) of the substrate support unit 11. The bias power supply 32 is configured to apply bias energy BE to the electrode of the substrate support unit 11 in order to draw ions from the plasma to the substrate W placed on the substrate support unit 11. In addition, the bias power supply 32 may be electrically connected to another electrode of the substrate support unit 11 instead of the base 114.

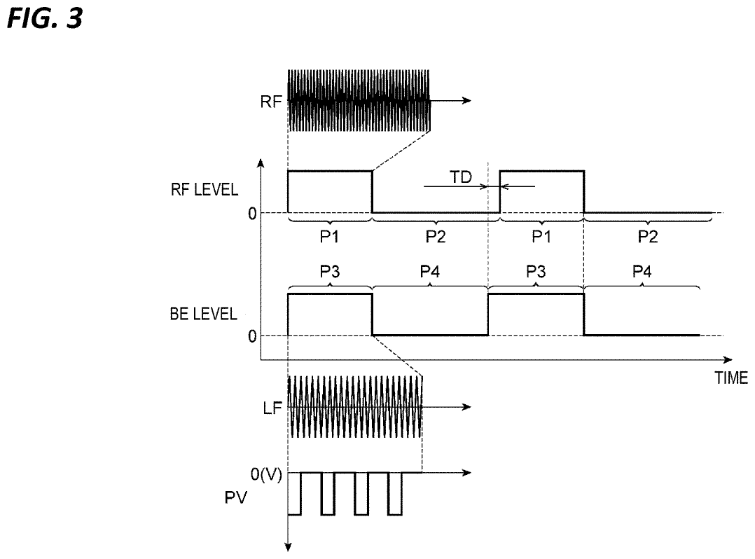

The bias energy BE may be radio-frequency power, i.e., radio-frequency bias power LF or a periodically generated voltage pulse PV (see, e.g., FIG. 3). The radio-frequency bias power LF has a bias frequency within the range of 400 kHz to 13.56 MHz. When the bias energy BE is the radio-frequency bias power LF, the bias power supply 32 is connected to the electrode of the substrate support 11 via a matching unit 32m. The matching unit 32m includes a matching circuit for matching the impedance of the load of the bias power supply 32 with the output impedance of the bias power supply 32.

The voltage pulse PV is generated with a cycle having a time length which is the reciprocal of the bias frequency. The bias frequency may be a frequency within the range of 100 kHz to 13.56 MHz. The voltage pulse PV may be a negative voltage pulse. The voltage pulse PV may be a negative DC voltage pulse. The voltage pulse PV may have an arbitrary waveform such as a rectangular pulse wave, a triangular pulse wave, or an impulse wave.

Hereinafter, reference will be made to FIG. 3 together with FIG. 2. FIG. 3 is a timing chart of an example of radio-frequency power and bias energy. As illustrated in FIG. 3, the radio-frequency power supply 31 modulates the radio-frequency power RF such that the level (watts) of the radio-frequency power RF in a first period P1 is higher than the level (watts) of the radio-frequency power RF in a second period P2. The second period P2 alternates with the first period P1. The level of the radio-frequency power RF in the second period P2 may be zero watts. That is, in one embodiment, the radio-frequency power supply 31 may be configured to stop the supply of the radio-frequency power RF in the second period P2. Alternatively, the level of the radio-frequency power RF in the second period P2 may be greater than zero watts. In addition, the modulation frequency, which is the reciprocal of the time length of a modulation cycle of the radio-frequency power RF each including the first period P1 and the second period P2, is lower than the bias frequency. The modulation frequency is, for example, a frequency within the range of 1 Hz to 100 kHz.

The bias power supply 32 modulates the bias energy BE such that the level of the bias energy BE in a third period P3 is higher than the level of the bias energy BE in a fourth period P4. The level of the bias energy BE is the power level when the bias energy BE is the radio-frequency bias power LF. The level of the bias energy BE is the absolute value of the voltage level of the pulse PV when the bias energy BE is the voltage pulse PV. The fourth period P4 alternates with the third period P3. The level of the bias energy BE in the fourth period P4 may be zero. That is, in one embodiment, the bias power supply 32 may be configured to stop the supply of the bias energy BE in the fourth period P4. Alternatively, the level of the bias energy BE in the fourth period P4 may be greater than zero. In addition, the time length of a modulation cycle of the bias energy BE each including the third period P3 and the fourth period P4 is the reciprocal of the above-described modulation frequency.

As illustrated in FIG. 3, the bias power supply 32 may initially supply the bias energy BE such that the start point of the third period P3 coincides with the start point of the first period P1. The bias power supply 32 is configured to adjust a time difference TD between the start point of the first period P1 and the start point of the third period P3 which partially overlaps with the first period P1 according to the power coupling efficiency of the radio-frequency power RF to the plasma.

The power coupling efficiency is an index indicating the coupling efficiency of the radio-frequency power RF to the plasma, and is obtained from the power Pf of a traveling wave and the power Pr of a reflected wave of the radio-frequency power RF. The power coupling efficiency is obtained from a formula of {(Pf−Pr)/Pf}×100%. Alternatively, the power coupling efficiency may be obtained from a formula of (Pf−Pr). In addition, the power Pf of the traveling wave and the power Pr of the reflected wave may be measured at the start point of the first period Pl.

In the plasma processing apparatus 1, the power Pf of the traveling wave and the power Pr of the reflected wave are measured by a gauge 34. The gauge 34 may be provided to measure the power Pf of the traveling wave and the power Pr of the reflected wave between the radio-frequency power supply 31 and the matching unit 31m. Alternatively, the gauge 34 may be provided to measure the power Pf of the traveling wave and the power Pr of the reflected wave between the matching unit 31m and the electrode (e.g., the base 114) of the substrate support 11.

The time difference TD according to the power coupling efficiency may be determined using a function or table prepared in advance. The power coupling efficiency and the time difference TD corresponding thereto may be obtained by the bias power supply 32. Alternatively, the power coupling efficiency and the time difference TD corresponding thereto may be obtained by the controller 2, and the obtained time difference TD may be designated from the controller 2 to the bias power supply 32.

In one embodiment, the bias power supply 32 may be configured such that the start point of the third period P3 precedes the start point of the first period P1, and the time difference TD increases as the power coupling efficiency decreases. Further, as illustrated in FIG. 3, the bias power supply 32 may set the time length of the third period P3 such that the end point of the first period P1 coincides with the end point of the third period P3 which partially overlaps with the first period P1.

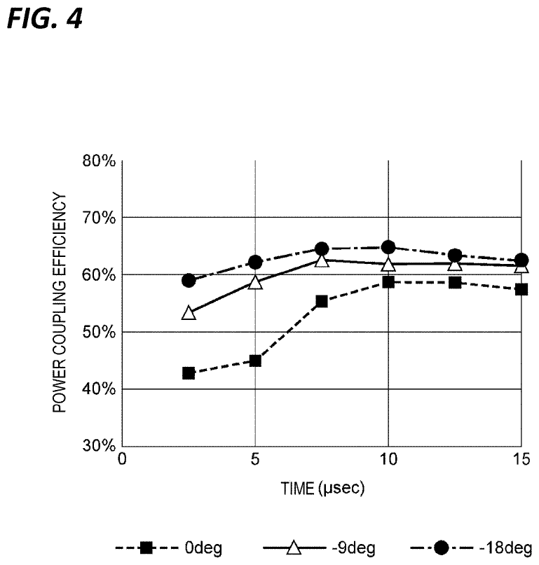

Hereinafter, reference will be made to FIG. 4. FIG. 4 is a diagram illustrating a time change in power coupling efficiency. The time change in three power coupling efficiencies illustrated in FIG. 4 is obtained by acquiring the power coupling efficiency of the radio-frequency power RF at the start point of the first period P1 using the plasma processing apparatus 1. The modulation frequency of the radio-frequency power RF and the bias energy BE are 400 kHz when the time change in the three power coupling efficiencies illustrated in FIG. 4 are acquired. The voltage pulse PV is used as the bias energy BE. In the acquisition of the time change in the three power coupling efficiencies illustrated in FIG. 4, three types of phase differences of 0 deg, −9 deg, and −18 deg are used as the phase difference between the modulation cycle of the bias energy BE and the modulation cycle of the radio-frequency power RF. That is, by setting the time difference TD between the start point of the third period P3 and the start point of the first period P1 subsequent thereto to 0 sec, 0.0625 μs, and 0.125 μs, the time change in the three power coupling efficiencies illustrated in FIG. 4 is acquired. As illustrated in FIG. 4, at the point when the supply of the pulse of the radio-frequency power RF is started, the larger the phase difference, i.e., the larger the time difference TD, the higher the power coupling efficiency of the radio-frequency power RF to the plasma.

As can be seen from the time change in the three power coupling efficiencies illustrated in FIG. 4, the time difference TD between the first period P1 and the third period P3 affects the coupling efficiency of the radio-frequency power RF to the plasma. According to the plasma processing apparatus 1, since the time difference TD is adjusted according to the power coupling efficiency of the radio-frequency power RF to the plasma, it is possible to increase the power coupling efficiency of the radio-frequency power RF in the generation of the plasma.

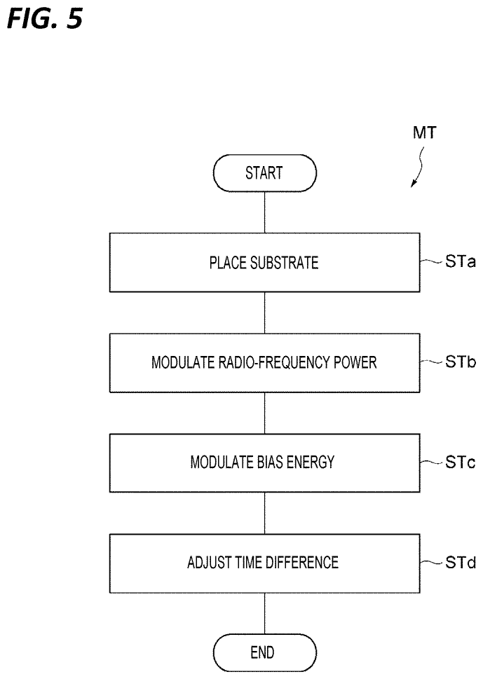

Hereinafter, a plasma processing method according to one embodiment will be described with reference to FIG. 5. FIG. 5 is a flowchart of a plasma processing method according to one embodiment. Hereinafter, the plasma processing method (hereinafter referred to as “method MT”) illustrated in FIG. 5 will be described by taking a case where the plasma processing apparatus 1 is used as an example. In addition, in each step of the method MT, each part of the plasma processing apparatus 1 may be controlled by the controller 2.

The method MT starts in step STa. In step STa, the substrate W is placed on the substrate support unit 11. Steps STb to STd of the method MT are executed in a state where the substrate W is placed on the substrate support unit 11. Further, in a period during which steps STb to STd are executed, a processing gas is supplied from the gas supply 20 into the chamber 10, and the pressure within the chamber 10 is adjusted by the exhaust system 40 to a designated pressure.

In step STb, the radio-frequency power RF is modulated. The radio-frequency power RF is supplied to generate plasma within the chamber 10. As described above, the radio-frequency power RF is modulated such that the level of the radio-frequency power RF in the first period P1 is higher than the level of the radio-frequency power RF in the second period P2.

In step STc, the bias energy BE is modulated. The bias energy BE is supplied to the electrode (e.g., the base 114) of the substrate support 11 in order to draw ions from the plasma to the substrate W. As described above, the bias energy BE is modulated such that the level of the bias energy BE in the third period P3 is higher than the level of the bias energy BE in the fourth period P4.

In step Std, the time difference TD between the start point of the first period P1 and the start point of the third period P3 which partially overlaps with the first period P1 is adjusted according to the power coupling efficiency of the radio-frequency power RF to the plasma. As described above, the power coupling efficiency is obtained from the power Pf of the traveling wave of the radio-frequency power RF and the power Pr of the reflected wave of the radio-frequency power acquired by the gauge 34. The power Pf of the traveling wave and the power Pr of the reflected wave may be measured at the start point of the first period P1.

In step STd, the time difference TD may be adjusted such that the start point of the third period P3 precedes the start point of the first period P1, and the time difference TD increases as the power coupling efficiency decreases. Further, the time length of the third period P3 may be set such that the end point of the first period P1 coincides with the end point of the third period P3 which partially overlaps with the first period P1.

Although various embodiments have been described above, various additions, omissions, substitutions, and changes may be made without being limited to the above-mentioned embodiments. Further, it is possible to combine elements in different embodiments to form other embodiments.

For example, in another embodiment, the plasma processing apparatus may be another capacitively-coupled plasma processing apparatus. Alternatively, the plasma processing apparatus may be another type of plasma processing apparatus such as an inductively-coupled plasma processing apparatus, an electron cyclotron resonance (ECR) plasma processing apparatus, or a plasma processing apparatus that generates plasma by a surface wave such as a microwave. Further, the method MT may be executed by using a plasma processing apparatus separate from the plasma processing apparatus 1.

According to one embodiment, it is possible to increase the power coupling efficiency of radio-frequency power in the generation of plasma.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a chamber:
a substrate support having an electrode and provided within the chamber;
a radio-frequency power supply configured to supply a radio-frequency power, thereby generating a plasma from a gas within the chamber;
a bias power supply configured to apply a bias energy to the electrode of the substrate support, thereby drawing ions from the plasma to a substrate placed on the substrate support; and
a gauge configured to measure a power of a traveling wave and a power of a reflected wave of the radio-frequency power,
wherein the radio-frequency power supply modulates the radio-frequency power such that a level of the radio-frequency power in a first period is higher than a level of the radio-frequency power in a second period alternating with the first period, and
wherein the bias power supply is configured to:
modulate the bias energy such that a level of the bias energy in a third period is higher than a level of the bias energy in a fourth period alternating with the third period; and
adjust a time difference between a start point of the first period and a start time point of the third period that partially overlaps with the first period according to a power coupling efficiency of the radio-frequency power to the plasma, obtained from the power of the traveling wave and the power of the reflected wave.

2. The plasma processing apparatus according to claim 1, wherein the bias power supply is configured to adjust the time difference such that the start point of the third period precedes the start point of the first period, and the time difference increases as the power coupling efficiency decreases.

3. The plasma processing apparatus according to claim 2, wherein the bias power supply sets a time length of the third period such that an end point of the first period coincides with an end point of the third period that partially overlaps with the first period.

4. The plasma processing apparatus according to claim 1, wherein the bias energy is a radio-frequency power or a pulse of a voltage that is periodically generated.

5. The plasma processing apparatus according to claim 1, wherein the radio-frequency power supply is configured to stop supply of the radio-frequency power in the second period, and
the bias power supply is configured to stop supply of the bias energy in the fourth period.

6. A plasma processing method comprising:
placing a substrate on a substrate support provided within a chamber of a plasma processing apparatus;
modulating a radio-frequency power supplied to generate a plasma within the chamber such that a level of the radio-frequency power in a first period is higher than a level of the radio-frequency power in a second period alternating with the first period;
modulating a bias energy supplied to an electrode of the substrate support to draw ions from the plasma to the substrate such that a level of the bias energy in a third period is higher than a level of the bias energy in a fourth period alternating with the third period; and
adjusting a time difference between a start point of the first period and a start point of the third period that partially overlaps with the first period according to a power coupling efficiency of the radio-frequency power to the plasma, obtained from a power of a traveling wave of the radio-frequency power and a power of a reflected wave of the radio-frequency power.

7. The plasma processing method according to claim 6, wherein the time difference is adjusted such that the start point of the third period precedes the start point of the first period, and the time difference increases as the power coupling efficiency decreases.

8. The plasma processing method according to claim 7, wherein a time length of the third period is set such that an end point of the first period coincides with an end point of the third period that partially overlaps with the first period.

9. The plasma processing method according to claim 6, wherein the bias energy is a radio-frequency power or a pulse of a voltage that is periodically generated.

10. The plasma processing method according to claim 6, wherein supply of the radio-frequency power is stopped in the second period, and supply of the bias energy is stopped in the fourth period.
